(19) United States
(12) Patent Application Publication
(10) Pub. No.: US 2006/0220196 A1
(43) Pub. Date: Oct. 5, 2006

(54) Semiconductor device and method of manufacturing the same, metal component and method of manufacturing the same

(75) Inventor: Mikio Oshima, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/391,369

(22) Filed: Mar. 29, 2006

(30) Foreign Application Priority Data
Mar. 31, 2005 (JP) 2005-105345

(51) Int. Cl. H01L 23/495

(52) U.S. Cl. 257/676

(57) ABSTRACT

A semiconductor device that includes: a metal component that has at least one face sealed with resin; a semiconductor element that is electrically or thermally connected to the metal component; and a protruding portion that is formed on the one face of the metal component by a push from the face opposite to the one face, at least one side of the protruding portion being connected to the metal component, another side of the protruding portion being separated from the metal component.

### BACKGROUND OF THE INVENTION

1. Field of the Invention

The present invention generally relates to a semiconductor device and a method of manufacturing the semiconductor device, and a metal component and a method of manufacturing the metal component, and more particularly, to a semiconductor device that has a semiconductor element sealed with resin, a method of manufacturing the semiconductor device, a metal component, and a method of manufacturing the metal component.

2. Description of the Related Art

Semiconductor devices that have semiconductor elements sealed with resin are used in various fields such as the field of household appliances, because it is possible to mass produce such semiconductor devices at low costs. A semiconductor device that has a semiconductor element sealed with resin includes a metal component that has at least one face sealed with resin, a metal component such as a lead frame or a heat radiating plate, and a semiconductor element that is electrically or thermally connected onto the metal component such as a lead frame or a heat radiating plate. The semiconductor element is sealed and covered with a resin sealing portion, so that the semiconductor element can be protected. If the adherence between the metal component and the resin sealing portion is poor in the resin-sealed semiconductor device, the resin might separate from the interface between the metal component and the resin. If the resin peels off, the semiconductor element might be damaged or even break.

To solve the problem, Japanese Unexamined Patent Publication No. 60-65553 discloses a semiconductor device that has grooves with inverse tapered faces on a heat radiating plate so as to prevent resin separation (prior art 1). Also, Japanese Unexamined Patent Publication No. 7-130915 discloses a semiconductor device that has grooves and protrusions on a heat radiating plate so as to prevent resin separation (prior art 2).

In the prior art 1, however, it is necessary to form a V-shaped groove next to each U-shaped groove after the formation of the U-shaped grooves. As for the prior art 2, the technique can be employed only where a heat radiating plate with a step portion is used. As is apparent from the prior arts, the formation of grooves and protrusions to increase the adherence with a metal plate is complicated. Furthermore, the adhesion between the metal component and the resin is not sufficient, and resin separation might be caused.

### SUMMARY OF THE INVENTION

It is therefore an object of the present invention to provide a semiconductor device, a method of manufacturing the semiconductor device, a metal component, and a method of manufacturing the metal component in which the above disadvantages are eliminated.

A more specific object of the present invention is to provide a semiconductor device that has high adherence between a metal component and resin so as to prevent resin separation, a method of manufacturing the semiconductor device, a metal component, and a method of manufacturing the metal component. The high adherence prevents the resin from separating from the metal component.

According to one aspect of the present invention, preferably, there is provided a semiconductor device including: a metal component that has at least one face sealed with resin; a semiconductor element that is electrically or thermally connected to the metal component; and a protruding portion that is formed by pushing a convex portion formed on the one face of the metal component.

According to another aspect of the present invention, preferably, there is provided a semiconductor device including: a metal component that has at least one face sealed with resin; a semiconductor element that is electrically or thermally connected to the metal component; and a protruding portion that is formed on the one face of the metal component by pushing a hole region penetrating the metal component from a face opposite to the one face.

According to another aspect of the present invention, preferably, there is provided a semiconductor device including: a metal component that has at least one face sealed with resin; a semiconductor element that is electrically or thermally connected to the metal component; and a protruding portion that is formed on the one face of the metal component by pushing from a face opposite to the one face and having a portion broken away from the metal component.

In accordance with the present invention, a semiconductor device that has high adherence between a metal component and resin so as to prevent resin separation can be provided.

According to another aspect of the present invention, preferably, there is provided a metal component that has at least one face sealed with resin, including: a protruding portion that is formed by pushing a convex portion formed on the one face of the metal component.

According to another aspect of the present invention, preferably, there is provided a metal component that has at least one face sealed with resin, including: a protruding portion that is formed on the one face of the metal component by pushing a hole region penetrating the metal component from a face opposite to the one face.

According to another aspect of the present invention, preferably, there is provided a metal component that has at least one face sealed with resin, including: a protruding portion that is formed on the one face of the metal component by pushing from a face opposite to the one face and having a portion broken away from the metal component.

In accordance with the present invention, a metal component that ensures high adherence between the metal component and resin so as to prevent resin separation can be provided.

According to another aspect of the present invention, preferably, there is provided a method of manufacturing a semiconductor device including: electrically or thermally connecting a semiconductor element and a metal component that has a protruding portion formed by pushing a convex portion formed on one face of the metal component; and sealing at least the one face of the metal component including the protruding portion and a semiconductor element with resin.

According to another aspect of the present invention, preferably, there is provided a method of manufacturing a semiconductor device including: electrically or thermally connecting a semiconductor element and a metal component that has a protruding portion formed on one face of the metal component by pushing a hole region penetrating the metal component from a face opposite to the one face; and sealing at least the one face of the metal component including the protruding portion and a semiconductor element with resin.

According to another aspect of the present invention, preferably, there is provided a method of manufacturing a semiconductor device including: electrically or thermally connecting a semiconductor element and a metal component that has a protruding portion that is formed on one face of the metal component having a portion broken away from the metal component by pushing from a face opposite to the one face; and sealing at least the one face of the metal component including the protruding portion and a semiconductor element with resin.

In accordance with the present invention, a method of manufacturing a semiconductor device that has high adherence between a metal component and resin so as to prevent resin separation can be provided.

According to another aspect of the present invention, preferably, there is provided a method of manufacturing a metal component that has at least one face sealed with resin, including: forming a convex portion on the one face of the metal component; and forming a protruding portion by pushing the convex portion. In accordance with the present invention, a method of manufacturing a metal component that ensures high adherence between the metal component and resin so as to prevent resin separation can be provided.

According to another aspect of the present invention, preferably, there is provided a method of manufacturing a metal component that has at least one face sealed with resin, including: forming a hole region that penetrates the metal component; and forming a protruding portion on the one face of the metal component by pushing the hole region from a face opposite to the one face. In accordance with the present invention, a method of manufacturing a metal component that ensures high adherence between the metal component and resin so as to prevent resin separation can be provided.

According to another aspect of the present invention, preferably, there is provided a method of manufacturing a metal component that has at least one face sealed with resin, including: forming a protruding portion having a portion broken away from the metal component on the one face of the metal component by pushing from a face opposite to the one face. In accordance with the present invention, a method of manufacturing a metal component that ensures high adherence between the metal component and resin so as to prevent resin separation can be provided.

The present invention can provide a semiconductor device that has high adherence between a metal component and resin so as to prevent resin separation, a method of manufacturing the semiconductor device, a metal component, and a method of manufacturing the metal component.

### BRIEF DESCRIPTION OF THE DRAWINGS

Other objects, features and advantages of the present invention will become more apparent from the following detailed description when read in conjunction with the accompanying drawings, in which:

FIG. 1 is a cross-sectional view of a semiconductor device in accordance with a first embodiment of the present invention;

FIGS. 2A through 2C are cross-sectional views illustrating a method of forming the protruding portions in accordance with the first embodiment;

FIGS. 3A through 3E are cross-sectional views illustrating modifications of the method of forming the protruding portions in accordance with the first embodiment;

FIG. 4A is a top view of a semiconductor device in accordance with a second embodiment of the present invention;

FIG. 4B is a cross-sectional and front view of the semiconductor device in accordance with the second embodiment;

FIG. 4C is a cross-sectional and side view of the semiconductor device in accordance with the second embodiment;

FIGS. 5A through 5C are cross-sectional views illustrating a method of forming the protruding portions in accordance with the second embodiment; and

FIGS. 6A through 6C are cross-sectional views illustrating a modification of the method of forming the protruding portions in accordance with the second embodiment.

### DESCRIPTION OF THE PREFERRED EMBODIMENTS

The following is a description of embodiments of the present invention, with reference to the accompanying drawings.

### First Embodiment

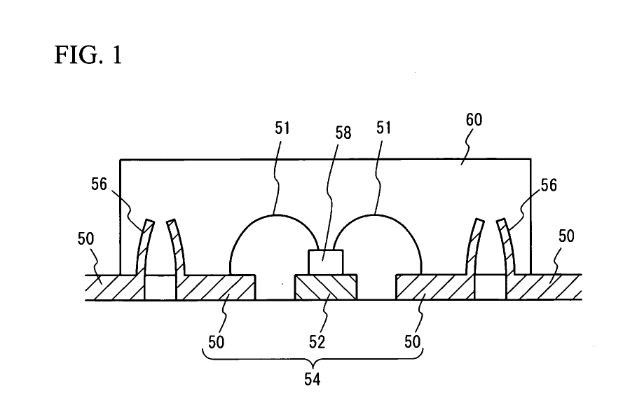

A first embodiment of the present invention is an example of a metal component that has a protruding portion formed on a lead frame. FIG. 1 is a cross-sectional view of a semiconductor device in accordance with the first embodiment. A lead frame 54 (a metal component) includes lead portions 50 that are electrically connected to a semiconductor element 58 with wires 51, a die pad portion 52 on which the semiconductor element 58 is mounted, and protruding portions 56 that are formed on the surface. The semiconductor element 58 is electrically or thermally connected onto the die pad portion 52. A resin sealing portion 60 is formed over the protruding portions 56 and the semiconductor element 58. The resin sealing portion 60 covers and protects the semiconductor element 58. In this manner, at least one face of the lead frame 54 (the metal component) is sealed with resin. Also, the protruding portions 56 increase the adherence between the resin of the resin sealing portion 60 and the lead frame 54. Although the die pad portion 52 is separated from the lead portion 50 in the first embodiment, the die pad portion 52 may be part of the lead portions 50. Also, the protruding portions 56 are formed on the lead portions 50, but they may be formed on portions other than the lead portions 50, as long as those portions are covered with the resin sealing portion 60. The bottom portion of the lead frame 54 (the metal component) may not be sealed with resin, but may be exposed to the outside. Here, the upper surface of the lead frame 54 (the metal component) is the face sealed with resin, and the bottom surface of the lead frame 54 is the face opposite to the upper surface.

The lead frame 54 mostly contains a metal such as Cu, a Cu alloy, or a Fe alloy. The semiconductor element 58 is secured onto the die pad portion 52 with AuSi, an Ag paste, or AuSn, for example. Further, the semiconductor element 58 is an IC chip containing transistors, and an optical semiconductor element such as a light emitting device or a light receiving device, for example. The resin sealing portion 60 mostly contains silicon resin or epoxy resin, for example. The shapes of the protruding portions 56 will be described later.

The semiconductor device in accordance with the first embodiment is manufactured in the following manner. The protruding portions 56 are formed on the lead portion 50 of the lead frame 54 (the metal component). The shapes of the protruding portions 56 will be described later. The semiconductor element 58 is tightly fixed (die-bonded) onto the die pad portion 52 with AuSi, an Ag paste, or AuSn, for example. By doing so, the lead frame 54 (the metal component) and the semiconductor element 58 are electrically or thermally connected to each other. The wires 51 are wire-bonded to the lead portions 50 and the semiconductor element 58 of the lead frame 54. Using a metal mold, a resin material containing silicon resin or epoxy resin, for example, is injected onto the protruding portions 56 and the semiconductor element 58. After the resin material hardens, the lead frame 54 is detached from the metal mold. Thus, the resin sealing portion 60 is formed. In this manner, at least one face (the upper surface) of the lead frame 54 (the metal component) and the semiconductor element 58 are sealed with resin.

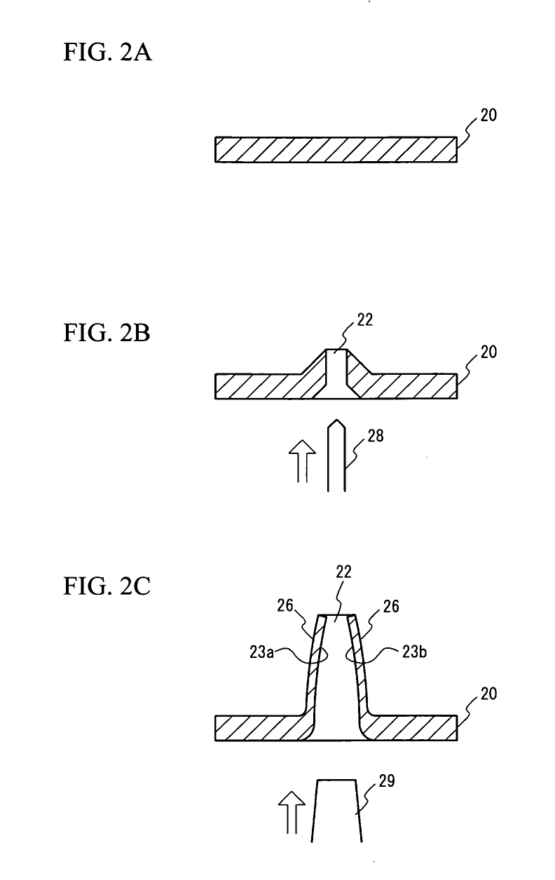

Next, a method of forming protruding portions on the upper surface (the resin-sealed face) of a lead frame is described. By this method, the protruding portions are formed by pushing a metal mold into hole regions penetrating the lead frame (a metal component) from the bottom surface (the opposite face from the resin-sealed face) of the lead frame. As shown in FIG. 2A, a lead frame 20 is prepared. As shown in FIG. 2B, hole regions 22 penetrating the lead frame 20 are formed with a metal mold 28 having a sharp edge, for example. As shown in FIG. 2C, a metal mold 29 having an edge with a larger diameter than the edge of the metal mold 28 (or a larger diameter than the diameter of each hole region 22) is forced into each of the hole regions 22 from the bottom surface (the opposite face from the resin-sealed face) of the lead frame 20. By doing so, protruding portions 26 are formed on the surface of the lead frame 20. Each of the protruding portions 26 has a ring-like shape with the hole region 22 formed in its center. The inner surface is inverse tapered, and the outer surface is forward tapered. Each of the protruding portions 26 has inverse tapered surfaces 23a and 23b extending in different directions. An inverse tapered surface is a face at an acute angle with respect to the resin-sealed face (the resin formation face) of the lead frame 20, and a forward tapered surface is a face at an obtuse angle with respect to the resin-sealed face (the resin formation face) of the lead frame 20.

As described above, the protruding portions 26 can be readily formed by pushing the two metal molds into the lead frame 20. Since the inverse tapered surfaces 23a and 23b of each protruding portion 26 extend in more than one direction, the adherence between the lead frame 20 and the resin can be increased. With protruding portions having inverse tapered surfaces extending in one direction, the resin adherence is low in relation to stress applied in a certain direction. For instance, in the prior art 1, inverse tapered faces extending in only one direction are formed by twice performing a groove forming operation. In the first embodiment, on the other hand, inverse tapered surfaces extending in more than one direction can be formed in each one protruding portion by twice performing a pushing operation. The protruding portions having the inverse tapered surfaces extending in more than one direction can increase the adherence between the lead frame and the resin. Furthermore, it is not necessary to form a step portion in the lead frame of the first embodiment, while a step portion is necessary in the lead frame of the prior art 2. Thus, a semiconductor device that has high resin adherence so as to prevent resin separation can be obtained by a simple manufacturing method.

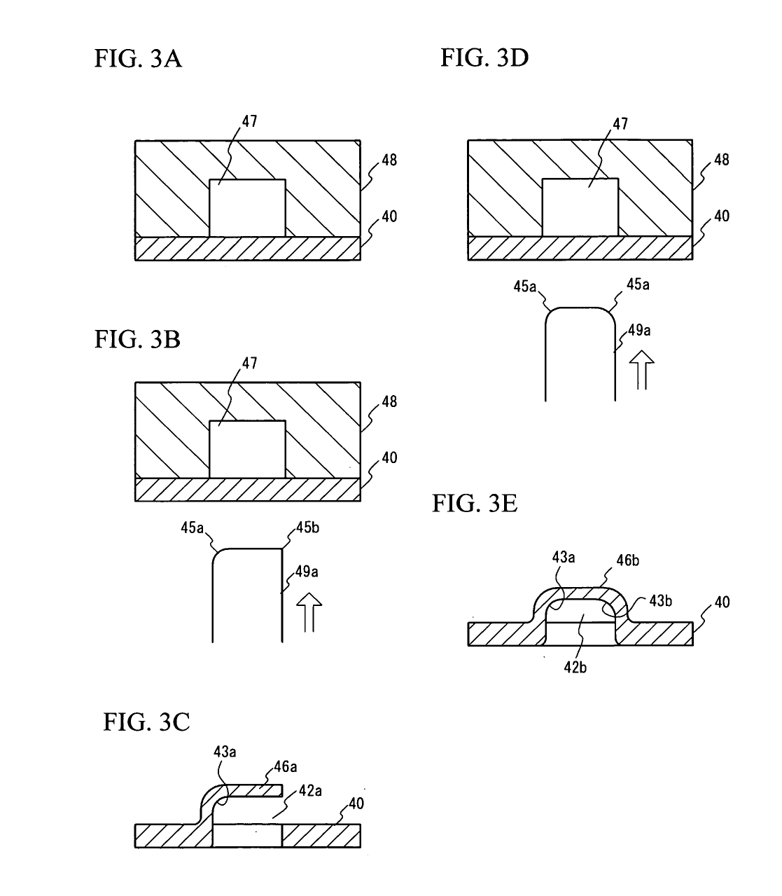

As a modification of the first embodiment, a method of forming a protruding portion having at least one side connected to a metal component and another side separated from the metal component is now described. Such a protruding portion is formed on the upper surface (the resin-sealed face) of a lead frame by a push from the bottom surface (the face opposite to the resin-sealed face) of the lead frame. As shown in FIG. 3A, a lead frame 40 is prepared, and a metal mold 25 having a convex portion 47 with a rectangular shape when seen from the bottom is brought into contact with part of the lead frame 40 from the upper surface of the lead frame 40. As shown in FIG. 3B, a metal mold 49a that is slightly smaller than the convex portion 47 and has an end face with a rectangular shape is pushed into the lead frame 40 from the bottom surface (the opposite face from the resin-sealed face) of the lead frame 40 located below the convex portion 47. The metal mold 49a has a side 45a with the larger curvature between the top end face and the corresponding side face, and a side 45b with the smaller curvature between the top end face and the corresponding side face. As shown in FIG. 3C, a protruding portion 46a is formed at each portion into which the side 45a with the larger curvature is pushed, and a hole region 42a is formed at each portion into which the side 45b with the smaller curvature is pushed on the surface of the lead frame 40. The protruding portion 46a has an inverse tapered face 43a.

Although the protruding portion 46a has only one end connected to the lead frame 40 while the other end is separated from the lead frame 40, this embodiment is not limited to this example. For example, a metal mold 49b having both sides 45a with large curvatures on either side of the top end face may be employed as shown in FIG. 3D. This metal mold 49b has small curvatures on the front side and the back side (not shown). As in the case illustrated in FIG. 3B, the metal 49b is also pushed into the lead frame 40. As shown in FIG. 3E, a protruding portion 46b having a semicircular shape when seen from a side is then formed on the surface of the lead frame 40, and the front and back sides of the lead frame 40 are cut off so as to form a hole region 42b.

In the above described modifications of the first embodiment, a metal mold with a side having a larger curvature between the end face and the corresponding side face (or the curvature formed by the end face and the corresponding side face) is pushed into a lead frame, or a metal mold with an end face having a corner with a large curvature) is pushed into a lead frame. By doing so, a protruding portion 46 is formed at the portion in which the side 45a having the larger curvature between the top end and the corresponding side face, and a hole region 42 is formed at the portion into which the side 45b with the smaller curvature. In this manner, a protruding portion that has at least one side connected to the lead frame (a metal component) and another side separated from the lead frame (the metal component) is formed. In a modification of the first embodiment, the protruding portion can be formed simply by once pushing a metal mold into the lead frame. Also, the arrangement of the side 45a with the larger curvature can be adjusted so as to form a protruding portion having the inverse tapered faces 43a and 43b extending in different directions. With such a protruding portion having inverse tapered faces extending in different directions, the adherence between the lead frame and the resin can be increased. Furthermore, it is not necessary to form a step portion in the lead frame, while it is necessary in the prior art 2. Thus, a semiconductor device that has high resin adherence so as to prevent resin separation can be obtained by a simple manufacturing method. A desired protruding portion of the present invention may have more than one side connected to the lead frame.

Also, the lead frame 54 of the first embodiment and its modifications includes the lead portions 50, the die pad portion 52 to which the semiconductor element 58 is to be secured, and protruding portions 56 formed on the surface of the lead frame 54 to be covered with the resin sealing portion 60. Using the lead frame 54, the semiconductor element 58 is fixed onto the die pad portion 52, and the resin sealing portion 60 is formed over the protruding portions 56 and the semiconductor element 58. In this manner, a semiconductor device that has high adherence between the lead frame 54 and the resin so as to prevent resin separation can be produced.

### Second Embodiment

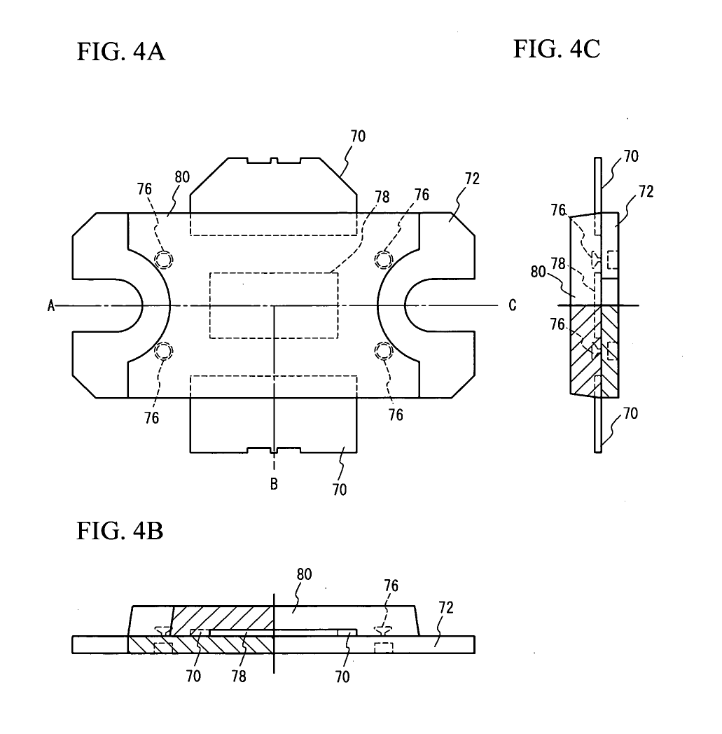

A second embodiment of the present invention is an example in which protruding portions 76 are formed on a heat radiating plate 72 as a metal component. FIGS. 4A through 4C illustrate a semiconductor device in accordance with the second embodiment. FIG. 4A is a top view of the semiconductor device. The left half of FIG. 4B is a cross-sectional view of the semiconductor device taken along the line A-B, and the right half of FIG. 4B is a front view of the semiconductor device. The lower half of FIG. 4C is a cross-sectional view of the semiconductor device taken along the line B-C, and the upper half of FIG. 4C is a side view of the semiconductor device. The heat radiating plate 72 (the metal component) has the protruding portions 76 formed on its surface, and a lead frame 70 that has a semiconductor element 78 secured onto its surface and has wires connecting the semiconductor element 78 and the lead frame 70. With this structure, the semiconductor element 78 is electrically or thermally connected to the heat radiating plate 72. A resin sealing portion 80 is formed over the protruding portions 76 and the semiconductor element 78. The semiconductor element 78 is protected by the resin sealing portion 80. In this manner, at least one face of the heat radiating plate 72 (the metal component) is sealed with resin. Also, the protruding portions 76 increase the adherence between the resin of the resin sealing portion 80 and the heat radiating plate 72. The semiconductor element 78 is tightly fixed onto the heat radiating plate 72 to release the heat generated from the semiconductor element 78. Here, the upper surface of the heat radiating plate 72 is the face sealed with resin, and the bottom surface of the heat radiating plate 72 is the face opposite to the upper surface.

The lead frame 70 and the heat radiating plate 72 mostly contain a metal such as Cu, a Cu alloy, or a Fe alloy. The semiconductor element 78 is secured onto the heat radiating plate 72 with AuSi, an Ag paste, or AuSn, for example. Further, the semiconductor element 78 is an IC chip containing transistors, and an optical semiconductor element such as a light emitting device or a light receiving device, for example. The resin sealing portion 80 mostly contains silicon resin or epoxy resin, for example. The heat radiating plate 72 may be integrally formed with the lead frame 70. The lead frame 70 may not include a die pad portion that is included in the lead frame of the first embodiment. Alternatively, a die pad portion is provided in the heat radiating plate 72, and the semiconductor element 78 is then fixed on to the heat radiating plate 72. The shapes of the protruding portions 76 will be described later.

The semiconductor device in accordance with the second embodiment is manufactured in the following manner. The protruding portions 76 are formed on the heat radiating plate 72. The shapes of the protruding portions 76 will be described later. The semiconductor element 78 is tightly fixed onto the heat radiating plate 72 with AuSi, an Ag paste, or AuSn, for example. By doing so, the heat radiating plate 72 (the metal component) and the semiconductor element 78 are electrically or thermally connected to each other. The wires are wire-bonded to the lead frame 70 and the semiconductor element 78. Using a metal mold, a resin material containing silicon resin or epoxy resin, for example, is injected onto the protruding portions 76 and the semiconductor element 78. After the resin material hardens, the heat radiating plate 72 is detached from the metal mold. Thus, the resin sealing portion 80 is formed. In this manner, at least one face (the upper surface) of the heat radiating plate 72 (the metal component) and the semiconductor element 78 are sealed with resin. Thus, the semiconductor device of the second embodiment is completed.

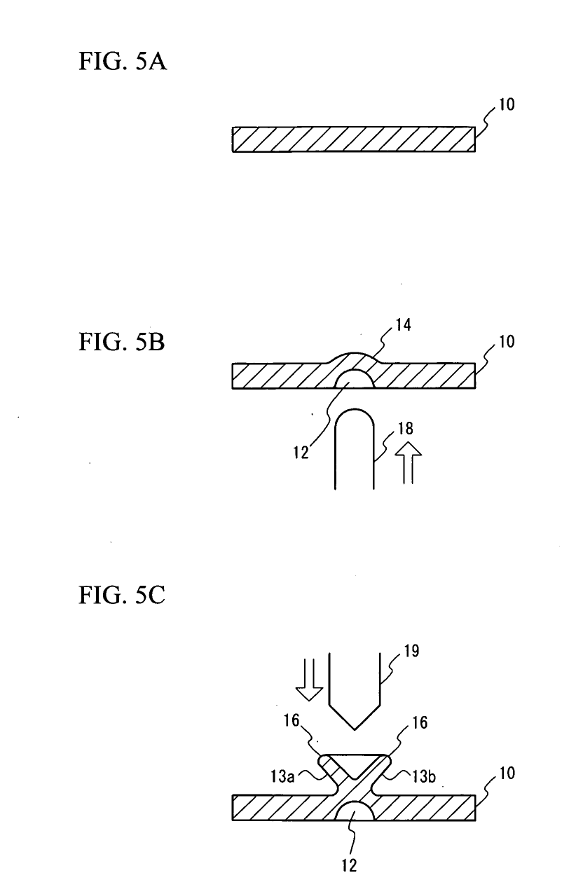

Next, a method of forming protruding portions on a heat radiating plate (a metal component) is described. By this method, the protruding portions are formed by pushing convex portions formed on the upper surface. As shown in FIG. 5A, a heat radiating plate 10 is prepared. As shown in FIG. 5B, a metal mold 18 that has a semicircular top end is pushed into a part of the heat radiating plate 10 from the bottom face (the opposite face from the face to which a semiconductor element is to be fixed) of the heat radiating plate 10. By doing so, a concave portion 12 with the same shape as the shape of the top end of the metal mold 18 is formed in the bottom face of the heat radiating plate 10, and a convex portion 14 is formed in the upper surface (the resin-sealed face) of the heat radiating plate 10. As shown in FIG. 5C, a metal mold 19 that has a sharper top end than the top end of the metal mold 18 is pushed into the convex portion 14 on the upper surface of the heat radiating plate 10. In this manner, the convex portion 14 is pressed to form protruding portions 16. Here, the convex portion 14 is slit into two. Thus, the protruding portions 16 are formed on the upper surface of the heat radiating plate 10. Each of the protruding portions 16 has a ring-like shape. The inner surface of each protruding portion 16 is inverse tapered, and the outer surface is forward tapered. Each of the protruding portions 16 has inverse tapered surfaces 13a and 13b extending in different directions. An inverse tapered surface is a face at an acute angle with respect to the upper surface of the heat radiating plate 10, and a forward tapered surface is a face at an obtuse angle with respect to the heat radiating plate 10. The concave portion 12 remains on the opposite side from the protruding portions 16.

As described above, the protruding portions 16 can be readily formed by pushing the two metal molds into the heat radiating plate 10. Since the inverse tapered surfaces 13a and 13b of each protruding portion 16 extend in more than one direction, the adherence between the heat radiating plate 10 and the resin can be increased. Thus, a semiconductor device that has high resin adherence so as to prevent resin separation can be obtained by a simple manufacturing method, as in the first embodiment.

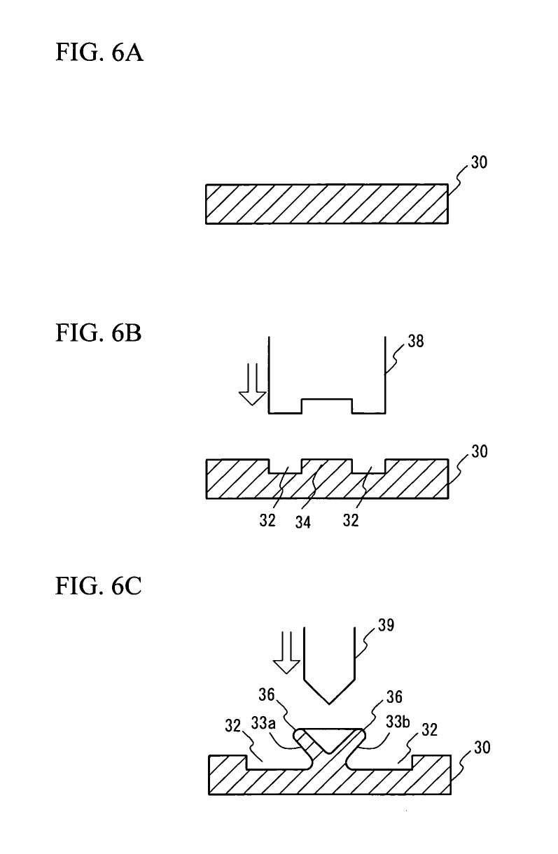

As a modification of the second embodiment, a method of forming protruding portions by pushing in a convex portion formed on the upper surface (the resin-sealed face) of a heat radiating plate (a metal component) is now described. As shown in FIG. 6A, a heat radiating plate 30 is prepared. As shown in FIG. 6B, a metal mold 38 that has more than one convex portions at its top end is pushed into a part of the heat radiating plate 30 from the upper surface (the resin-sealed face), so as to form a convex portion 34 interposed between two or more concave portions 32 on the upper surface of the heat radiating plate 30. As shown in FIG. 6C, a metal mold 39 that has a sharp top end is pushed into the convex portion 34 from the upper surface (the resin-sealed face) of the heat radiating plate 30, so as to form slit portion. By doing so, a protruding portion 36 is formed on the upper surface of the heat radiating plate 30. The protruding portion 36 is interposed between the concave portions 32. The inner face the protruding portion 36 is forward tapered, and the outer face is inverse tapered. The protruding portion 36 has inverse tapered faces 33a and 33b extending in different directions.

In the above described modification of the second embodiment, protruding portions can be readily formed using two metal molds. As the protruding portion 36 has the inverse tapered faces 33a and 33b extending in different directions, the adherence between the heat radiating plate and the resin can be increased. Thus, a semiconductor device that has high resin adherence so as to prevent resin separation can be obtained by a simple manufacturing method, as in the first embodiment.

Also, protruding portions may be formed by the same method as that of the first embodiment or each of the modifications of the first embodiment. In such a case, the same effects as those of the first embodiment or each of the modifications can be achieved.

Also, the heat radiating plate 72 of the second embodiment and its modification has the lead frame 72 secured thereto, and has the protruding portions 76 formed on the upper surface of the heat radiating plate 72 over which the resin sealing portion 80 is to be formed. Using the heat radiating plate 72, the semiconductor element 78 is fixed onto the upper surface of the heat radiating plate 72, and the resin sealing portion 80 is formed over the protruding portions 76 and the semiconductor element 78 to be secured onto the upper surface. In this manner, a semiconductor device that has high adherence between the heat radiating plate 72 and the resin so as to prevent resin separation can be produced.

In the first and second embodiments, it is preferable to provide two or more protruding portions so as to prevent resin separation. In a case where two protruding portions are to be formed, it is preferable to arrange the two protruding portions along the center line of a lead frame or a heat radiating plate. Thus, the resin adherence can be increased.

In the first and second embodiments, a resin sealing portion is formed using a metal mold. However, a resin sealing portion may be formed by a so-called potting method, without the use of a metal mold. Although protruding portions are formed on a lead portion of a lead frame or a heat radiating plate in each of the above described embodiments, the same effects as those of each of the embodiments can be achieved, as long as a metal component that can be sealed with resin and can be electrically or thermally connected to a semiconductor element is employed. For example, a protruding portion may be formed on a die pad portion or a lead portion.

The lead frame 54 of the first embodiment, the heat radiating plate 72 of the second embodiment, or a lead portion (a lead) or a die pad portion (a die pad) having the same protruding portions as those described above, can be employed as a metal component for producing a semiconductor device. With such a metal component, a semiconductor device that has high adherence between the metal component and resin so as to prevent resin separation can be produced.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A semiconductor device comprising:
a metal component that has at least one face sealed with resin;
a semiconductor element that is electrically or thermally connected to the metal component; and
a protruding portion that is formed by pushing a convex portion formed on the one face of the metal component.

2. A semiconductor device comprising:
a metal component that has at least one face sealed with resin;
a semiconductor element that is electrically or thermally connected to the metal component; and
a protruding portion that is formed on the one face of the metal component by pushing a hole region penetrating the metal component from a face opposite to the one face.

3. A semiconductor device comprising:
a metal component that has at least one face sealed with resin;
a semiconductor element that is electrically or thermally connected to the metal component; and
a protruding portion that is formed on the one face of the metal component by pushing from a face opposite to the one face and having a portion broken away from the metal component.

4. The semiconductor device as claimed in claim 1, wherein the metal component is a lead unit that is electrically connected to the semiconductor element, a die pad on which the semiconductor element is mounted, or a heat radiating plate.

5. The semiconductor device as claimed in claim 1, wherein the face opposite to the one face of the metal component is an exposed face that is not sealed with the resin.

6. The semiconductor device as claimed in claim 1, wherein a plurality of protruding portions are formed on the metal component.

7. A metal component that has at least one face sealed with resin, comprising:
a protruding portion that is formed by pushing a convex portion formed on the one face of the metal component.

8. A metal component that has at least one face sealed with resin, comprising:
a protruding portion that is formed on the one face of the metal component by pushing a hole region penetrating the metal component from a face opposite to the one face.

9. A metal component that has at least one face sealed with resin, comprising:
a protruding portion that is formed on the one face of the metal component by pushing from a face opposite to the one face and having a portion broken away from the metal component.

10. The metal component as claimed in claim 7, wherein the metal component is a lead unit that is electrically connected to the semiconductor element, a die pad on which the semiconductor element is mounted, or a heat radiating plate.

11. The metal component as claimed in claim 7, wherein the face opposite to the one face of the metal component is an exposed face that is not sealed with the resin.

12. The metal component as claimed in claim 7, wherein a plurality of protruding portions are formed on the metal component.

13. A method of manufacturing a semiconductor device, comprising the steps of:
electrically or thermally connecting a semiconductor element and a metal component that has a protruding portion formed by pushing a convex portion formed on one face of the metal component; and
sealing at least the one face of the metal component including the protruding portion and a semiconductor element with resin.

14. A method of manufacturing a semiconductor device, comprising the steps of:
electrically or thermally connecting a semiconductor element and a metal component that has a protruding portion formed on one face of the metal component by pushing a hole region penetrating the metal component from a face opposite to the one face; and
sealing at least the one face of the metal component including the protruding portion and a semiconductor element with resin.

15. A method of manufacturing a semiconductor device, comprising the steps of:
electrically or thermally connecting a semiconductor element and a metal component that has a protruding portion that is formed on one face of the metal component having a portion broken away from the metal component by pushing from a face opposite to the one face; and
sealing at least the one face of the metal component including the protruding portion and a semiconductor element with resin.

16. The method as claimed in claim 13, wherein the metal component is a lead to which the semiconductor element is wire-bonded.

17. The method as claimed in claim 13, wherein the metal component is a die pad to which the semiconductor element is wire-bonded.

18. The method as claimed in claim 13, wherein the metal component is a heat radiating plate that is thermally connected directly to the semiconductor element or is thermally connected to the semiconductor element via a die pad on which the semiconductor element is mounted.

19. A method of manufacturing a metal component that has at least one face sealed with resin, comprising the steps of:
forming a convex portion on the one face of the metal component; and
forming a protruding portion by pushing the convex portion.

20. The method as claimed in claim 19, wherein the step of forming the protruding portion includes splitting the convex portion.

21. A method of manufacturing a metal component that has at least one face sealed with resin, comprising the steps of:
forming a hole region that penetrates the metal component; and
forming a protruding portion on the one face of the metal component by pushing the hole region from a face opposite to the one face.

22. The method as claimed in claim 21, wherein the step of forming the protruding portion includes pushing the hole region with a metal mold that has a larger diameter than that of the hole region.

23. A method of manufacturing a metal component that has at least one face sealed with resin, comprising the step of:
forming a protruding portion having a portion broken away from the metal component on the one face of the metal component by pushing from a face opposite to the one face.

24. The method as claimed in claim 23, wherein the push is carried out with a metal mold that has a top end with a corner having a large curvature.

25. The method as claimed in claim 19, wherein the metal component is a lead unit that is electrically connected to the semiconductor element, a die pad on which the semiconductor element is mounted, or a heat radiating plate.

26. The method as claimed in claim 19, wherein a plurality of protruding portions are formed.
